(19) United States
(12) Patent Application Publication
(10) Pub. No.: US 2026/0188177 A1
(43) Pub. Date: Jul. 2, 2026

(54) DISPLAY DEVICE

(71) Applicant: LG Display Co., Ltd., Seoul (KR)

(72) Inventor: JeongHo Kim, Seoul (KR)

(73) Assignee: LG Display Co., Ltd., Seoul (KR)

(21) Appl. No.: 19/431,287

(22) Filed: Dec. 23, 2025

(30) Foreign Application Priority Data
Dec. 31, 2024 (KR) 10-2024-0202395

(51) Int. Cl. G09G 3/20

(52) U.S. Cl. CPC G09G 3/2096; G09G 2300/0426; G09G 2300/0842; G09G 2310/0286; G09G 2330/021; G09G 2380/10

(57) ABSTRACT

A display device includes at least one pixel disposed on a display area and including at least one light emitting element, the at least one light emitting element emitting light based on a first power voltage, a second power voltage, a third power voltage, a gate signal, and a data signal. The display device further includes a gate driver disposed on the display area and including at least one stage, the at least one stage generating the gate signal based on the first power voltage, a fourth power voltage, a start signal, a reset signal, a first clock signal, and a second clock signal. The display area includes a plurality of areas that do not overlap the at least one pixel, the at least one stage is disposed in the plurality of areas. The at least one pixel and the at least one stage share at least one power line.

### CROSS-REFERENCE TO RELATED APPLICATION

This application claims the priority of Korean Patent Application No. 10-2024-0202395, filed on Dec. 31, 2024, in the Korean Intellectual Property Office, the disclosure of which is incorporated herein by reference.

### BACKGROUND

### Field

The present disclosure relates to a display device.

### Description of the Related Art

As the world enters an information era, a display field which visually expresses electrical information signals has been rapidly developed, and in response to this, various display devices having excellent performances such as thin-thickness, light weight, and low power consumption have been developed. Examples of such a display device include a liquid crystal display device (LCD) and an organic light emitting display device (OLED).

Such a display device may include a display panel in which pixels for displaying an image are disposed, a data driver which supplies a data signal to pixels through data lines, a gate driver which supplies a gate signal to pixels through gate lines, and a timing controller which controls the data driver and the gate driver.

### SUMMARY

An object to be achieved by the present disclosure is to provide a display device which improves a pattern density of a display area in which a pixel is disposed.

Another object to be achieved by the present disclosure is to provide a display device which minimizes or reduces parasitic capacitance.

Objects of the present disclosure are not limited to the above-mentioned objects, and other objects, which are not mentioned above, can be clearly understood by those skilled in the art from the following descriptions.

To achieve these objects and other advantages and in accordance with an aspect of the present disclosure, as embodied and broadly described herein, a display device includes: at least one pixel disposed on a display area and including at least one light emitting element, the at least one light emitting element emitting light based on a first power voltage, a second power voltage, a third power voltage, a gate signal, and a data signal; and a gate driver disposed on the display area and including at least one stage, the at least one stage generating the gate signal based on the first power voltage, a fourth power voltage, a start signal, a reset signal, a first clock signal, and a second clock signal. The display area includes a plurality of areas that do not overlap the at least one pixel, and the at least one stage is disposed in the plurality of areas. The at least one pixel and the at least one stage share at least one power line.

In another aspect of the present disclosure, a display device includes: at least one pixel disposed in a display area including a plurality of areas that are sequentially spaced apart along a first direction, the at least one pixel being disposed so as not to overlap the plurality of areas; a gate driver including at least one stage disposed in the plurality of areas on the display area; at least one power line disposed in the plurality of areas and extending in a second direction different from the first direction; and at least one connection pattern extending in the first direction and connected to the at least one power line. At least one transistor included in the at least one stage is connected to the at least one connection pattern, and at least one transistor included in the at least one pixel is connected to the at least one connection pattern.

Other detailed matters of various example embodiments are included in the detailed description and the drawings.

In the display device according to one or more example embodiments of the present disclosure, various components (e.g., transistors, capacitors, etc.) included in each stage of the gate driver and wiring lines connected thereto to provide various signals and voltages are disposed in the display area (e.g., a gate-in-array (GIA) structure), so that the bezel area of the display device may be minimized or reduced.

Further, in the display device according to one or more example embodiments of the present disclosure, a high potential power voltage (e.g., a first power voltage) may be provided to each stage of the gate driver by using a power line (e.g., a first power line) for providing a high potential power voltage (e.g., a first power voltage) to the pixel. That is, in the display device according to one or more example embodiments of the present disclosure, each stage of the gate driver and the pixel may share the first power line that provides the first power voltage.

Accordingly, since the number of power lines in the display area decreases, pattern density may be improved, and parasitic capacitance between lines may be minimized or reduced.

The effects according to example embodiments of the present disclosure are not limited to the contents exemplified above, and various additional effects can be attained from the present disclosure.

### BRIEF DESCRIPTION OF DRAWINGS

The accompanying drawings, which are included to provide a further understanding of the present disclosure and are incorporated in and constitute a part of this application, illustrate embodiments of the present disclosure and together with the description serve to explain various principles of the disclosure. The above and other aspects, features and other advantages of the present disclosure will be more clearly understood from the following detailed description taken in conjunction with the accompanying drawings.

FIG. 1A is an example diagram of a display device according to one or more example embodiments of the present disclosure.

FIG. 1B is an example plan view of a display device according to one or more example embodiments of the present disclosure.

FIG. 2 is a block diagram illustrating a display device according to one or more example embodiments of the present disclosure.

FIG. 3 is a circuit diagram illustrating an example of a pixel included in a display device of FIG. 2.

FIG. 4 is a cross-sectional view illustrating a display device according to one or more example embodiments of the present disclosure.

FIG. 5A is a diagram illustrating an example of a first optical member disposed on a first light emitting element included in the pixel of FIG. 3.

FIG. 5B is a view illustrating an example of a second optical member disposed on the second light emitting element included in the pixel of FIG. 3.

FIG. 6 is a circuit diagram illustrating an example of a gate driver included in a display device of FIG. 2.

FIG. 7A is a view illustrating an example of a display area of the display device of FIG. 2.

FIG. 7B is a view illustrating another example of the display area of the display device of FIG. 2.

FIG. 8 is an enlarged layout diagram illustrating an example of a part EA1 of FIG. 7A.

FIG. 9 is an enlarged layout diagram illustrating an example of a part EA2 of FIG. 7A.

FIG. 10 is an enlarged layout diagram illustrating an example of a part EA3 of FIG. 7A.

FIG. 11 is an enlarged layout diagram illustrating an example of a part EA4 of FIG. 7A.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with a more specific term like “only.” Any references to singular may include plural, and vice versa, unless expressly stated otherwise.

Components are to be interpreted to include an ordinary error range even if not expressly stated.

Where the position relation between two parts is described using such terms as “on,” “above,” “below,” and “next,” one or more parts may be positioned between the two parts unless the terms are used with a more specific term like “immediately” or “directly.” Where an element or layer is described as being disposed “on” another element or layer, another layer or another element may be interposed directly on the other element or therebetween.

Although the terms “first,” “second,” and the like may be used for describing various components, these components are not confined by these terms. These terms are merely used for referring to one component separately from the other components. Therefore, a first component to be mentioned below may be a second component, and vice versa, in a technical concept of the present disclosure.

Like reference numerals generally denote like elements throughout the disclosure, unless otherwise specified.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings.

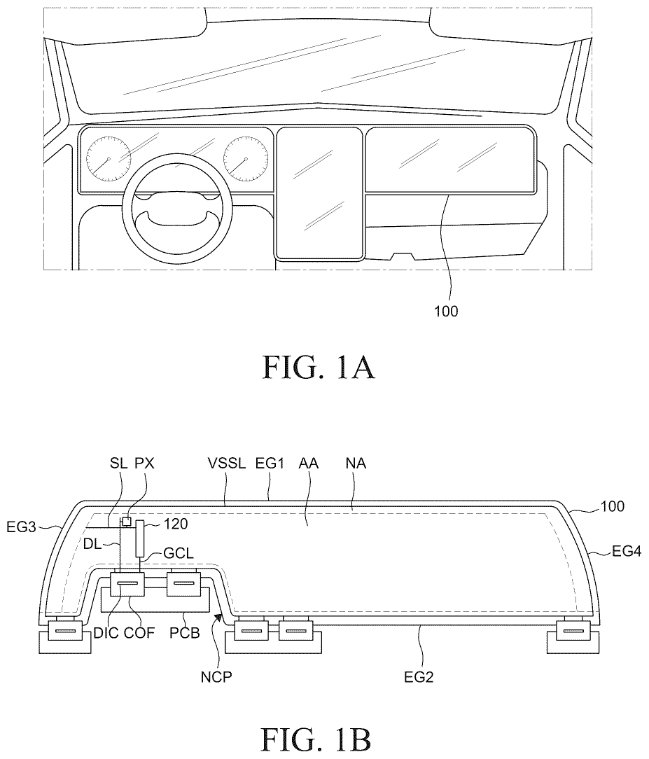

FIG. 1A is an example diagram of a display device according to one or more example embodiments of the present disclosure.

FIG. 1B is an example plan view of a display device according to one or more example embodiments of the present disclosure.

As shown in FIGS. 1A and 1B, the display device 100 may be disposed on at least a part of a dashboard of a vehicle. The dashboard of the vehicle may include a configuration disposed in front of front seats (e.g., driver's seat and passenger seat) of the vehicle. For example, an input configuration for manipulating various functions (e.g., an air conditioner, an audio system, and a navigation system) inside the vehicle may be disposed on the dashboard of the vehicle.

The display device 100 may be disposed on the dashboard of the vehicle and operate as an input unit for manipulating at least some of various functions of the vehicle. The display device 100 may provide various information related to the vehicle, for example, driving information of the vehicle (for example, a current speed of the vehicle, a remaining fuel amount, and a driving distance), information on parts of the vehicle (for example, a damage degree of a vehicle tire), and the like. Embodiments are not limited thereto. As an example, the display device 100 may provide various information not related to the vehicle. As an example, the display device 100 may be disposed on any position inside the vehicle other than the dashboard of the vehicle. As an example, the display device 100 may be not disposed in a vehicle, but may be disposed in a monitor of a computer, a laptop, a tablet, a mobile phone, a TV, a signage, a building, a theater, a household appliance, etc., without being limited thereto.

As an example, the display device 100 may be disposed across the driver seat and the front passenger seat disposed in the front seats of the vehicle. The user of the display device 100 may include a driver of the vehicle and a passenger riding in the passenger seat. Both the driver and the passenger of the vehicle may use the display device 100. Embodiments are not limited thereto. As an example, the display device 100 may be disposed to correspond to only one of the driver seat and the front passenger seat disposed in the front seats of the vehicle, and may be used by corresponding one of the driver and the passenger of the vehicle, without being limited thereto.

Only a part of the display device 100 illustrated in FIG. 1A may be illustrated. The display device 100 illustrated in FIG. 1A may represent a display panel among various configurations included in the display device 100. Specifically, for example, the display device 100 illustrated in FIG. 1A may represent at least a part of a display area and a non-display area of a display panel. Among the components of the display device 100, components other than those illustrated in FIG. 1A may be mounted inside (or at least a part of) the vehicle, without being limited thereto.

As shown in FIG. 1B, the display device 100 may have a general rectangular shape, but may have various shapes, such as a circular shape, a square shape, a triangle shape, a polygonal shape, an oval shape, etc., depending on a product to which the display device 100 is to be applied. For example, when the display device 100 is applied to the vehicle, the display device 100 may have a heterogeneous shape having curved surfaces SE1 and SE2 and a notch portion NCP as illustrated in FIG. 1B.

Specifically, as an example, the display device 100 may include an upper first edge EG1 extending in a straight line, a lower second edge EG2 having a notch portion NCP, a left third edge EG3 formed of a curved surface, and a right fourth edge EG4 formed of a curved surface.

In the notch portion NCP, a portion of the display device 100 may be notched and formed to be concave. Embodiments are not limited thereto. As an example, the notch portion NCP may be omitted depending on the design.

The display area AA may also include edges corresponding to the edges EG1, EG2, EG3 and EG4 of the display device 100. The display area AA may include a concave portion corresponding to the notch portion NCP, a convex side portion corresponding to the curved third edge EG3 and the fourth edge EG4, and the like.

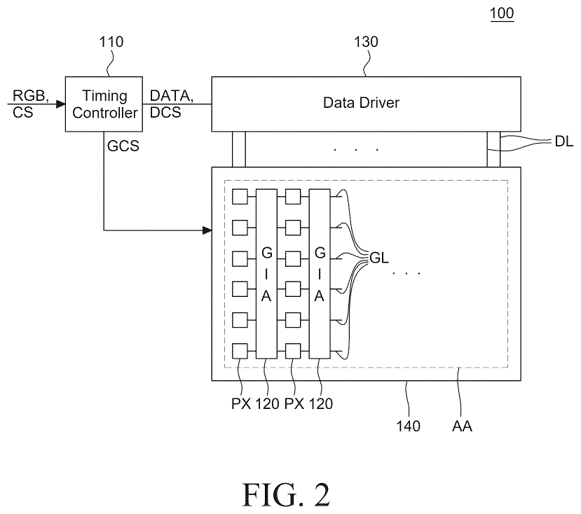

As an example, the plurality of flexible films COF each including the driving IC DIC may be connected to the second edge EG2 of the display device 100. The flexible film COF may be a film in which various components are disposed on a base film having flexibility. For example, the flexible film COF may include a data driver (e.g., the data driver 130 of FIG. 2), and a driving IC DIC, which is a component that processes data for displaying images and driving signals, may be disposed on the flexible film COF. As an example, some of the plurality of flexible films COF may be connected to a part of the second edge EG2 corresponding to the notch portion NCP, and the rest may be connected to the rest of the second edge EG2 excluding the notch portion NCP, without being limited thereto.

The printed circuit board PCB may be electrically connected to one or more flexible films COF and supply signals to the driving IC DIC. The printed circuit board PCB may be electrically connected to the flexible film COF. Various components for supplying various signals to the driving IC DIC may be disposed on the printed circuit board PCB. For example, various components such as a timing controller (e.g., the timing controller 110 of FIG. 2), a power management integrated circuit (PMIC), a memory, or a processor may be disposed on the printed circuit board (PCB), without being limited thereto.

As an example, the gate driver 120 may be disposed on the display area AA, without being limited thereto. The gate driver 120 may be driven by receiving a signal from the flexible film COF through the gate driving line GCL.

The low potential power line VSSL may be disposed in the non-display area NA. The low potential power line VSSL may receive a signal from the flexible film COF. The low potential power line VSSL is disposed to surround the display area AA and may transmit a low potential power voltage to the display area AA. The low potential power line VSSL may be disposed along the edges EG1, EG2, EG3, and EG4 of the display device 100 and may have a shape corresponding to the edges EG1, EG2, EG3, and EG4 of the display device 100, without being limited thereto.

Accordingly, the display device 100 is applied to various products and may be formed in a heterogeneous shape, and configurations such as the gate driver 120, the flexible film COF, and the low potential power line VSSL may be disposed to correspond to the heterogeneous shape, without being limited thereto.

FIG. 2 is a block diagram illustrating a display device according to one or more example embodiments of the present disclosure.

As shown in FIG. 2, a display device 100 according to one or more example embodiments of the present disclosure may include a timing controller 110, a gate driver 120, a data driver 130, and a display panel 140.

The display panel 140 may generate an image to be provided to a user. For example, the display panel 140 may include a plurality of pixels PX in which pixel circuits are disposed in the display area AA. Each of the plurality of pixels PX is connected to a corresponding gate line GL and a data line DL to display an image in response to a gate signal provided to the gate line GL and a data signal provided to the data line DL.

The timing controller 110 may control the gate driver 120 and the data driver 130 based on an input image RGB and an input control signal CS provided from the outside, for example, a host system. For example, the input control signal CS includes timing signals such as a horizontal synchronization signal, a vertical synchronization signal, a data enable signal, and a clock signal and the timing controller 110 may generate a gate control signal GCS and a data control signal DCS based on the input control signal CS. The gate control signal GCS may be provided to the gate driver 120, and the data control signal DCS may be provided to the data driver 130.

Further, the timing controller 110 rearranges the input image RGB in the digital video data format to match the resolution of the display panel 140 to generate image data DATA and provide the image data to the data driver 130.

The gate driver 120 may generate a gate signal based on the gate control signal GCS and output the gate signal to the plurality of gate lines GL. For example, the gate driver 120 may sequentially output gate signals to the plurality of gate lines GL in units of horizontal lines.

For example, the gate driver 120 may generate a scan signal and an emission signal based on the gate control signal GCS. For example, the gate driver 120 may include a scan driver and an emission driver. The scan driver generates a scan signal in a row sequential manner to drive at least one scan signal line connected to each pixel row to supply the scan signal to the scan signal lines. The emission driver generates an emission signal in a row sequential manner to drive at least one emission signal line connected to each pixel row to supply the emission signal to the emission signal lines.

In an example embodiment, the gate driver 120 is formed in a thin film pattern shape when manufacturing a substrate of the display panel 140 to be formed in a gate-in-array (GIA) manner on the display area AA in which the pixels PX of the display panel 140 are disposed. Accordingly, a bezel area of the display device 100 may be minimized or reduced.

The data driver 130 converts digital image data DATA provided from the timing controller 110 into an analog data signal based on the data control signal DCS to supply the analog data signal to the plurality of data lines DL.

One pixel PX may include a plurality of sub-pixels emitting light of different colors. For example, one pixel PX may implement blue, red, and green colors using three sub-pixels. However, the present disclosure is not limited thereto, and in some cases, the pixel PX may further include a sub-pixel for further implementing a specific color, for example, white. As an example, one pixel PX may include two, three, four or more sub-pixels, without being limited thereto.

In the pixel PX, an area implementing blue may be referred to as a blue sub-pixel, an area implementing red may be referred to as a red sub-pixel, and an area implementing green may be referred to as a green sub-pixel. Although it is described that one pixel PX may include a plurality of sub-pixels, the expression “pixel PX” herein below may refer to one pixel or one sub-pixel, without an explicit distinction therebetween.

Each of the plurality of pixels PX may include a first light emitting element and a second light emitting element which emit light of the same color.

Each of the plurality of pixels PX may include a first optical member that refracts light from the first light emitting element in a specific direction and a second optical member that refracts light from the second light emitting element in a specific direction, without being limited thereto. For example, each of the first optical member and the second optical member may be implemented as a lens, but the embodiments of the present disclosure are not limited thereto.

For example, the first optical member may be disposed in an optical area that provides light in a first range to form a first viewing angle, and the second optical member may be disposed in an optical area that provides light in a second range to form a second viewing angle. The first range may correspond to a range wider than the second range. Accordingly, the first optical member and the second optical member may limit the viewing angle of each of the plurality of pixels PX. Embodiments are not limited thereto. As an example, at least one of or each of the first optical member and the second optical member may be omitted depending on the design.

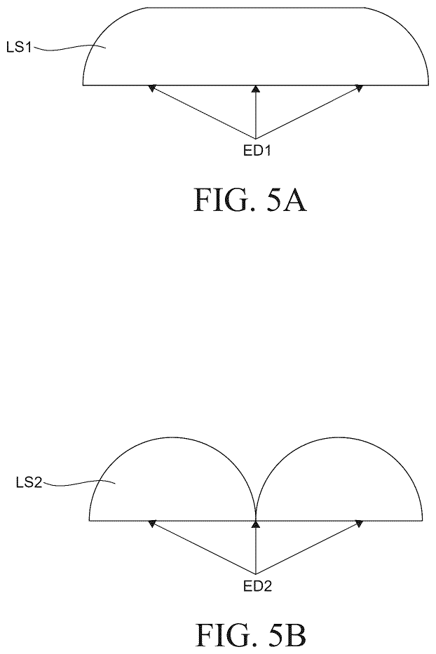

The first optical member and the second optical member will be described in detail below with reference to FIGS. 5A and 5B.

According to the one or more example embodiments, when the display panel 140 is used in the vehicle described with reference to FIG. 1, a field of view of at least a part of an image displayed on the display panel 140 needs to be restricted according to a driving mode. For example, among contents included in an image displayed on the display panel 140, contents related to an entertainment function and seat information for a passenger sitting in the passenger seat may interfere with the driver's driving of the vehicle. Therefore, the viewing angle of the corresponding contents may be restricted according to a user demand or a driving mode.

Accordingly, to limit the field of view of at least some of the content included in the display image, each pixel PX included in the display panel 140 may be driven in the first mode or the second mode. For example, when the pixel PX is driven in the first mode, the first light emitting element included in the pixel PX emits light based on the selection signal to provide light from the first light emitting element to the first range through the first optical member to form the first viewing angle, for example, a wide viewing angle. Further, when the pixel PX is driven in the second mode, the second light emitting element included in the pixel PX emits light based on the selection signal to provide the light from the second light emitting element to the second range through the second optical member to form the second viewing angle, for example, a narrow viewing angle. Here, the first mode corresponds to a mode in which the pixel PX is controlled in a wide-view (share) mode, and the second mode corresponds to a mode in which the pixel PX is driven in a narrow-view (private) mode.

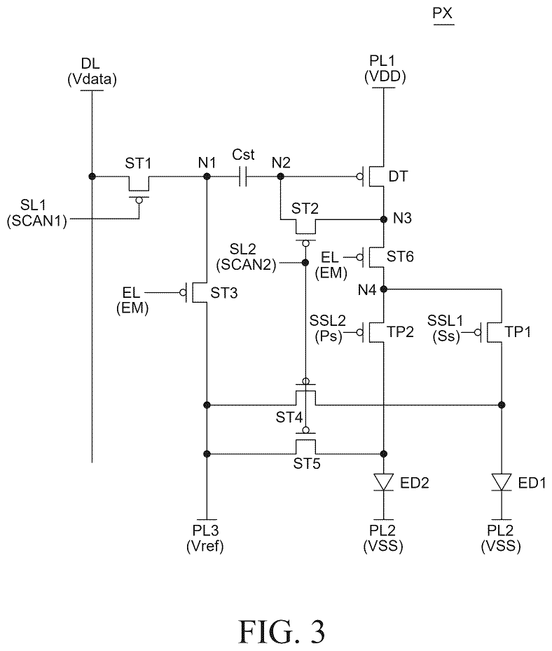

FIG. 3 is a circuit diagram illustrating an example of a pixel included in a display device of FIG. 2.

For example, the pixel PX illustrated in FIG. 3 represents an example embodiment of a pixel circuit corresponding to each of the plurality of sub pixels of one pixel PX included in the display device 100 described with reference to FIG. 2.

As shown in FIG. 3, the driving transistor DT, a plurality of switching transistors ST1 to ST6, a plurality of selection transistors TP1 and TP2, a storage capacitor Cst, and a plurality of light emitting elements ED1 and ED2 may be included.

The driving transistor DT may be connected between a first power line PL1 configured to provide a first power voltage VDD and a second power line PL2 configured to provide a second power voltage VSS. The driving transistor DT may control a driving current applied to the plurality of light emitting elements ED1 and ED2 according to a source-gate voltage. For example, the driving transistor DT may control a first driving current applied to the first light emitting element ED1 and a second driving current applied to the second light emitting element ED2. For example, the driving transistor DT may control a first driving current flowing from the first power line PL1 to the second power line PL2 via the first light emitting element ED1 and a second driving current flowing from the first power line PL1 to the second power line PL2 via the second light emitting element ED2 in response to a voltage of the second node N2 which is a gate electrode. To this end, the first power voltage VDD may be set to a voltage higher than the second power voltage VSS. For example, the first power voltage VDD may be a positive voltage, and the second power voltage VSS may be a negative voltage, without being limited thereto.

Meanwhile, the second power line PL2 may be a low potential power line VSSL that transmits the low potential power voltage described with reference to FIG. 1B.

The first switching transistor ST1 may be connected between the data line DL providing a data signal Vdata and the first node N1. The first switching transistor ST1 includes a gate electrode connected to the first scan signal line SL1 to which the first scan signal SCAN1 is applied, and may be turned on or turned off by the first scan signal SCAN1. For example, the first switching transistor ST1 may provide the data signal Vdata to the first node N1 in response to a low level of first scan signal SCAN1 which is a turn-on level. Although it is described that the turn-on level of the first switching transistor ST1 is a low level of the first scan signal SCAN1, embodiments are not limited thereto. As an example, the turn-on level of the first switching transistor ST1 may be a low level or a high level of the first scan signal SCAN depending on the type (e.g., n-type or p-type) of the first switching transistor ST1. The same applies to the remaining transistors of the pixel circuit, without being limited thereto.

The second switching transistor ST2 may be connected between the gate electrode and the drain electrode of the driving transistor DT, for example, the second node N2 and the third node N3. The second switching transistor ST2 may include a gate electrode connected to the second scan signal line SL2 to which the second scan signal SCAN2 is applied, and may be turned on or turned off by the second scan signal SCAN2. For example, the second switching transistor ST2 may diode-connect the gate electrode and the drain electrode of the driving transistor DT in response to a low level of second scan signal SCAN2 which is a turn-on level.

The third switching transistor ST3 may be connected between the first node N1 and a third power line PL3 configured to provide the reference voltage Vref. The third switching transistor ST3 includes a gate electrode connected to the light emission signal line EL to which the light emission control signal EM is applied, and may be turned on or turned off by the light emission control signal EM. For example, the third switching transistor ST3 may apply the reference voltage Vref to the first node N1 in response to an emission control signal EM having a low level which is a turn-on level.

The fourth switching transistor ST4 may be connected between the first electrode of the first light emitting element ED1, e.g., the anode electrode and the third power line PL3. The fourth switching transistor ST4 may include a gate electrode connected to the second scan signal line SL2 to be turned on or turned off by the second scan signal SCAN2. For example, the fourth switching transistor ST4 may apply the reference voltage Vref to the first electrode of the first light emitting element ED1 in response to the second scan signal SCAN2 at a low level, i.e., a turn-on level.

The fifth switching transistor ST5 may be connected between the first electrode of the second light emitting element ED2, for example, the anode electrode and the third power line PL3. The fifth switching transistor ST5 includes a gate electrode connected to the second scan signal line SL2 to be turned on or turned off by the second scan signal SCAN2. For example, the fifth switching transistor ST5 may apply the reference voltage Vref to the first electrode of the second light emitting element ED2 in response to the second scan signal SCAN2 at a low level, i.e., a turn-on level.

The sixth switching transistor ST6 may form a current path between the driving transistor DT and any one of the plurality of light emitting elements ED1 and ED2. The sixth switching transistor ST6 may be connected between the third node N3 and the fourth node N4. The sixth switching transistor ST6 includes a gate electrode connected to the emission signal line EL to be turned on or turned off by the emission control signal EM. When the sixth switching transistor ST6 is turned on, the third node N3 and the fourth node N4 may be electrically connected to form a first current path between the driving transistor DT and the first light emitting element ED1 or a second current path between the driving transistor DT and the second light emitting element ED2.

The storage capacitor Cst may be connected between the first node N1 and the second node N2. For example, the storage capacitor Cst may include a first electrode connected to the first node N1 and a second electrode connected to the second node N2. The storage capacitor Cst may store a predetermined voltage to maintain a constant voltage of the gate electrode of the driving transistor DT while the first light emitting element ED1 or the second light emitting element ED2 emits light.

The plurality of selection transistors TP1 and TP2 may include a first selection transistor TP1 for generating a current path of a first driving current passing through the first light emitting element ED1 and a second selection transistor TP2 for generating a current path of a second driving current passing through the second light emitting element ED2.

The first selection transistor TP1 may be connected between the fourth node N4 and the first light emitting element ED1, and the gate electrode of the first selection transistor TP1 may be connected to the first selection signal line SSL1 configured to provide the first selection signal Ss. When the pixel PX is driven in a first mode, which is a wide-view mode, the first selection signal Ss is supplied such that the first selection transistor TP1 may be turned on. Accordingly, a current path of the first driving current passing through the first light emitting element ED1 is formed, such that the first light emitting element ED1 may emit light.

The second selection transistor TP2 may be connected between the fourth node N4 and the second light emitting element ED2, and the gate electrode of the second selection transistor TP2 may be connected to the second selection signal line SSL2 configured to provide the second selection signal Ps. When the pixel PX is driven in a second mode, which is a narrow-view mode, the second selection signal Ps is supplied to the gate electrode of the second selection transistor TP2, so the second selection transistor TP2 may be turned on. Accordingly, a current path for the second driving current passing through the second light emitting element ED2 is formed, such that the second light emitting element ED2 may emit light.

The first light emitting element ED1 may be connected between the first selection transistor TP1, which is turned on or off by the first selection signal Ss, and the second power line PL2 that provides the second power voltage VSS. The second light emitting element ED2 may be connected between the second selection transistor TP2, which is turned on or off by the second selection signal Ps, and the second power line PL2.

In this case, the first light emitting element ED1 or the second light emitting element ED2 may be connected to another component of the pixel PX, for example, the driving transistor DT by the first selection transistor TP1 or the second selection transistor TP2, which is turned on according to the driving mode. For example, the first light emitting element ED1 is connected to the driving transistor DT via the first selection transistor TP1 turned on in the first mode, and the first driving current in the first mode, that is, the wide-view mode, may cause light to be provided at the first viewing angle, which is a wide viewing angle. In addition, the second light-emitting element ED2 is connected to the driving transistor DT via the second selection transistor TP2, which is turned on in the second mode, that is, narrow-view mode. In the second mode, by the second driving current, light may be provided at a narrow viewing angle, which is the second viewing angle. Here, the driving mode may be designated by a user's input or determined when a predetermined condition is satisfied, without being limited thereto. Although it is illustrated that the pixel circuit of the pixel PX may include the driving transistor DT, a plurality of switching transistors ST1 to ST6, a plurality of selection transistors TP1 and TP2, a storage capacitor Cst, and a plurality of light emitting elements ED1 and ED2, embodiments are not limited thereto. As an example, the configuration of the pixel circuit may be changed in various ways. As an example, at least one or more of the above-mentioned transistors or capacitor may be omitted, and at least one or more additional transistors or capacitor may be further included, without being limited thereto.

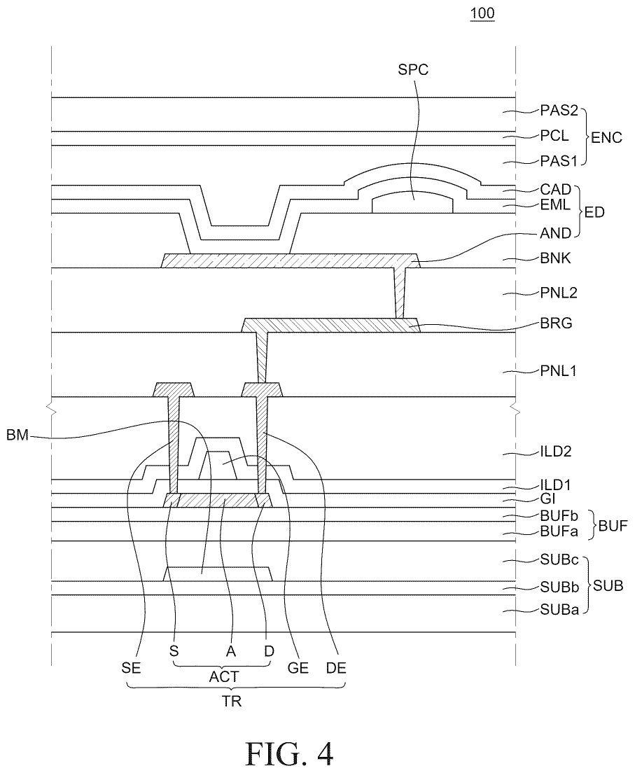

FIG. 4 is a cross-sectional view illustrating a display device according to one or more example embodiments of the present disclosure.

For example, FIG. 4 illustrates a cross-sectional view illustrating an example of a pixel PX included in the display device 100. For example, the transistor TR illustrated in FIG. 4 may be any one of the driving transistor DT, a plurality of switching transistors ST1 to ST6, and a plurality of selection transistors TP1 and TP2 included in the pixel PX described with reference to FIG. 3.

Further, in FIG. 4, the light emitting element ED connected to the pixel PX is illustrated together, and the light emitting element ED may be any one of a plurality of light emitting elements ED (e.g., the first light emitting element ED1 and the second light-emitting element ED2) included in the pixel PX described with reference to FIG. 3.

As shown in FIG. 4, the transistor TR and the light emitting element ED may be disposed on the substrate SUB.

The substrate SUB is a base material of the display panel 140 and may be a substantially transparent light-transmitting substrate. The substrate SUB may be a flexible substrate made of a plastic material, or thin glass, or a rigid substrate, without being limited thereto. For example, the substrate SUB may include polyimide (PI), without being limited thereto.

Meanwhile, when the substrate SUB includes polyimide PI, moisture penetrates through the substrate SUB made of polyimide PI and penetrates into a thin film transistor included in the pixel PX, thereby reducing the reliability of the pixel PX, which may degrade the performance of the display device 100.

Accordingly, in an example embodiment, the substrate SUB may include double polyimide (PI), without being limited thereto. Further, the substrate SUB further includes an inorganic film formed between the two polyimides (PI) so that the reliability of the product performance may be further improved by blocking the moisture component from passing through the lower polyimide (PI). In addition, an inorganic film is formed between the two polyimides (PI) to block charges charged in the lower polyimide (PI), thereby further improving the reliability of the product.

For example, as illustrated in FIG. 4, the substrate SUB may include a first sub substrate SUBa including polyimide (PI), a second sub substrate SUBb disposed on the first sub substrate SUBa and including an inorganic insulating material, and a third sub substrate SUBc disposed on the second sub substrate SUBb and including polyimide (PI).

Meanwhile, this is example, and the substrate SUB may be a rigid substrate including glass or tempered glass.

A light shielding layer BM may be disposed on the substrate SUB. The light shielding layer BM is disposed below the semiconductor layer of the transistor TR and may include a metal material. As described above, the light shielding layer BM including a metal material is disposed below the transistor TR which is a polysilicon semiconductor transistor, such that the threshold voltage shift of the corresponding transistor may be prevented or suppressed, thereby improving reliability.

To this end, the light shielding layer BM may be disposed to overlap at least a part of the semiconductor layer of the transistor TR, for example, the semiconductor pattern ACT. As an example, the light shielding layer BM may be omitted depending on the design.

The buffer layer BUF may be disposed on the substrate SUB. For example, the buffer layer BUF may be disposed on the substrate SUB to cover the light shielding layer BM.

The buffer layer BUF may serve to improve adhesion between components formed thereon and the substrate SUB and block moisture or oxygen permeating through the substrate SUB.

For example, the buffer layer BUF may include a multi-buffer layer BUFa disposed on the substrate SUB and an active buffer layer BUFb disposed on the multi-buffer layer BUFa, but is not limited thereto.

The transistor TR may be disposed on the buffer layer BUF. For example, the semiconductor pattern ACT, the gate electrode GE, the source electrode SE, and the drain electrode DE of the transistor TR may be disposed on the buffer layer BUF.

A semiconductor layer may be disposed on the buffer layer BUF. For example, the semiconductor layer is a semiconductor layer including polysilicon and may form a semiconductor pattern of at least one of the driving transistor DT, the plurality of switching transistors ST1 to ST6, and the plurality of selection transistors TP1 and TP2 described above with reference to FIG. 3. Embodiments are not limited thereto. As an example, the semiconductor layer may be a semiconductor layer including other semiconductors such as an oxide semiconductor, a compound semiconductor, an organic semiconductor, an amorphous semiconductor, etc., without being limited thereto.

For example, the semiconductor pattern ACT of the transistor TR may be disposed on the buffer layer BUF. The semiconductor pattern ACT of the transistor TR may include a first region S, a second region D, and a channel region A therebetween. For example, each of the first region S and the second region D may be a source region and a drain region of the semiconductor pattern ACT.

A gate insulating layer GI may be disposed on the buffer layer BUF. For example, the gate insulating layer GI is disposed on the buffer layer BUF so as to cover the semiconductor pattern ACT of the semiconductor layer, for example, the transistor TR, to insulate the semiconductor pattern ACT of the transistor TR from the gate electrode GE.

The gate electrode GE of the transistor TR may be disposed on the gate insulating layer GI. The gate electrode GE of the transistor TR may be disposed to overlap at least a portion of the semiconductor pattern ACT.

A first insulating layer ILD1 may be disposed on the gate insulating layer GI. For example, the first insulating layer ILD1 may be disposed on the gate insulating layer GI to cover the gate electrode GE of the transistor TR.

A second insulating layer ILD2 may be disposed on the first insulating layer ILD1. The second insulating layer ILD2 may planarize an upper portion and cover components disposed therebelow. Meanwhile, according to an example embodiment, the first insulating layer ILD1 and the second insulating layer ILD2 may be formed as one insulating layer.

The source electrode SE and the drain electrode DE of the transistor TR may be disposed on the second insulating layer ILD2. The source electrode SE and the drain electrode DE of the transistor TR may be in contact with the first region S and the second region D of the semiconductor pattern ACT through at least one contact hole penetrating through the second insulating layer ILD2, the first insulating layer ILD1, and the gate insulating layer GI, respectively.

A first planarization layer PNL1 may be disposed on the second insulating layer ILD2. For example, the first planarization layer PNL1 is disposed on the second insulating layer ILD2 so as to cover the source electrode SE and the drain electrode DE of the transistor TR to planarize the upper portion and protect components disposed therebelow.

The bridge electrode BRG may be disposed on the first planarization layer PNL1. The bridge electrode BRG may be in contact with the transistor TR, for example, the drain electrode DE of the transistor TR through at least one contact hole penetrating through the first planarization layer PNL1. Embodiments are not limited thereto. As an example, the bridge electrode BRG may be omitted depending on the design.

The second planarization layer PNL2 may be disposed on the first planarization layer PNL1. For example, the second planarization layer PNL2 may be disposed on the first planarization layer PNL1 to cover the bridge electrode BRG.

The second planarization layer PNL2 may be an organic layer for planarizing an upper portion and protecting components disposed therebelow.

The light emitting element ED may be disposed on the second planarization layer PNL2. The light emitting element ED includes a first electrode and a second electrode, for example, an anode electrode AND and a cathode electrode CAD, and may include an emission layer EML formed therebetween.

The anode electrode AND may be disposed on the second planarization layer PNL2. The anode electrode AND may be connected to the bridge electrode BRG through a through hole which passes through the second planarization layer PNL2 to expose at least a part of the bridge electrode BRG, or may be directly connected to the drain electrode DE of the transistor TR without the bridge electrode BRG. Accordingly, the anode electrode AND may be connected to the drain electrode DE of the transistor TR through the bridge electrode BRG.

The bank layer BNK may be disposed to cover at least a part of the anode electrode AND and may expose the remaining part of the anode electrode AND. For example, the bank layer BNK may be disposed so that a portion corresponding to the emission area of the pixel PX is exposed. Accordingly, a part of the anode electrode AND may be exposed by the open part of the bank layer BNK. Meanwhile, a spacer SPC may be further disposed on the bank layer BNK.

The emission layer EML may be disposed on the front surface of the pixel PX over the bank layer BNK and the anode electrode AND. Meanwhile, a part of the emission layer EML may be in contact with the exposed part of the anode electrode AND by the open part of the bank layer BNK.

The cathode electrode CAD may be disposed on the emission layer EML. For example, at least a part of the second power line PL2 (or the low potential power line VSSL) configured to provide the second power voltage VSS to the pixel PX may constitute the cathode electrode CAD of the light emitting element ED. Embodiments are not limited thereto. As an example, the cathode electrode CAD of the light emitting element ED may be separately provided, and then connected to the second power line PL2 (or the low potential power line VSSL) to be supplied with the second power voltage VSS.

The light emitting element ED may be formed by the anode electrode AND, the emission layer EML, and the cathode electrode CAD.

An encapsulation layer ENC may be disposed on the light emitting element ED to protect the light emitting element ED of the pixel PX from external moisture permeation.

The encapsulation layer ENC may have a single layer or a multilayer structure. For example, the encapsulation layer ENC may include a first encapsulation layer PAS1, a second encapsulation layer PAS2, and a third encapsulation layer PCL between the first encapsulation layer PAS1 and the second encapsulation layer PAS2.

The encapsulation layer ENC may include a transparent material to transmit light emitted from the light emitting element ED. For example, the first encapsulation layer PAS1 and the second encapsulation layer PAS2 may include an inorganic material having transparency, and the third encapsulation layer PCL may be disposed between the first encapsulation layer PAS1 and the second encapsulation layer PAS2 and include an organic material having transparency, without being limited thereto.

FIG. 5A is a diagram illustrating an example of a first optical member disposed on a first light emitting element included in the pixel of FIG. 3.

FIG. 5B is a view illustrating an example of a second optical member disposed on the second light emitting element included in the pixel of FIG. 3.

As shown in FIGS. 3, 5A, and 5B, the first optical member LS1 may be disposed above the first light emitting element ED1 included in one pixel PX, and the second optical member LS2 may be disposed above the second light emitting element ED2 included in one pixel PX. Meanwhile, as described with reference to FIG. 2, the first light-emitting element ED1 and the second light-emitting element ED2 included in one pixel PX may emit light of the same color.

As shown in FIG. 5A, the first optical member LS1 may be disposed on the first light emitting element ED1. Light generated by the first light emitting element ED1 of each pixel PX may be emitted through the first optical member LS1 of the corresponding pixel PX. The first optical member LS1 may have a shape in which light in at least one direction may not be restricted. For example, a planar shape of the first optical member LS1 positioned in each of the pixels PX may be a bar shape extending in one direction.

In this case, the propagation direction of the corresponding light emitted through the first optical member LS1 of each pixel PX may not be limited to one direction. For example, the content (or images) provided through the first optical member LS1 of each pixel PX may be shared with surrounding people adjacent to the user in one direction. Accordingly, the content provided by the light emitted through the first optical member LS1 may be provided within a first viewing angle range, which has a wider viewing angle than a viewing angle range of content provided by light emitted through the second optical member LS2. For example, the content provided by the light emitted through the first optical member LS1 may be provided as a share view to users and surrounding people within the first viewing angle range.

As shown in FIG. 5B, the second optical member LS2 may be disposed on the second light emitting element ED2. The light generated by the second light emitting element ED2 of each pixel PX may be emitted through the second optical member LS2 of the corresponding pixel PX. The second optical member LS2 may limit the propagation direction of light passing through the second optical member LS2 to one direction and/or another direction. For example, a planar shape of the second optical member LS2 positioned in each of the pixels PX may be a circular shape.

In this case, the propagation direction of the light emitted through the second optical member LS2 of each pixel PX may be limited to one direction and/or another direction. For example, the content (or images) provided through the second optical member LS2 of each pixel PX may not be shared with people around the user. Accordingly, the content provided by the light emitted through the second optical member LS2 may be provided within a second viewing angle range, which has a narrower viewing angle than a viewing angle range of content provided by light emitted through the first optical member LS1. For example, the content provided by the light emitted through the second optical member LS2 may not be shared with people around the user and may be provided as a private view within the second viewing angle range.

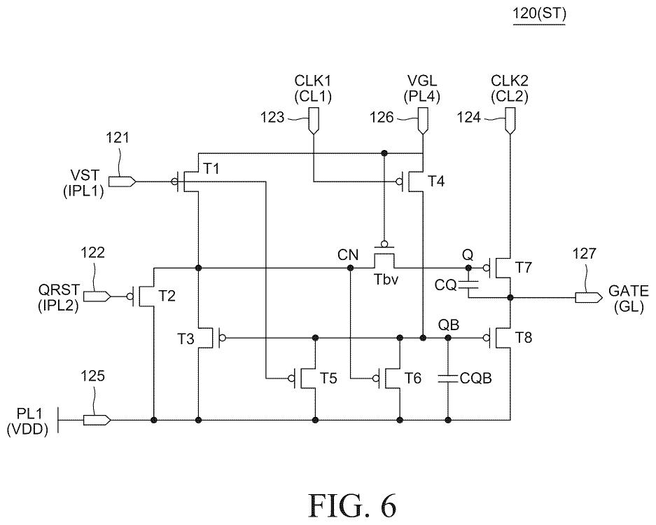

FIG. 6 is a circuit diagram illustrating an example of a gate driver included in a display device of FIG. 2. For example, FIG. 6 illustrates a circuit diagram illustrating an example of any one of a plurality of stages ST included in the scan driver or the emission driver included in the gate driver 120.

As shown in FIG. 6, the stage ST included in the gate driver 120 is connected to the first input signal line IPL1 through the first input terminal 121 to receive the start signal VST, is connected to the second input signal line IPL2 through the second input terminal 122 to receive the reset signal QRST, and is connected to the first clock line CL1 through the third input terminal 123 to receive the first clock signal CLK1, and is connected to the second clock line CL2 through the fourth input terminal 124 to receive the second clock signal CLK2.

In an example embodiment, the stage ST included in the gate driver 120 may be connected to the first power line PL1 configured to provide the pixel PX with the first power voltage VDD and receive the first power voltage VDD. For example, the stage ST may be connected to the first power line PL1 through the first power input terminal 125. In addition, the stage ST may be connected to a fourth power line PL4 through the second power input terminal 126 to receive the fourth power voltage VGL. The first power voltage VDD may be a high potential voltage for driving the stage ST, and the fourth power voltage VGL may be a low potential voltage for driving the stage ST. For example, the first power voltage VDD may be set to a voltage higher than the fourth power voltage VGL. For example, the first power voltage VDD may be a positive voltage, and the fourth power voltage VGL may be a negative voltage, without being limited thereto.

The stage ST included in the gate driver 120 may output the gate signal GATE to the output terminal 127 connected to the gate line GL based on the start signal VST, the reset signal QRST, the first clock signal CLK1, the second clock signal CLK2, the first power voltage VDD, and the fourth power voltage VGL.

To this end, the stage ST included in the gate driver 120 may include a plurality of transistors T1 to T8, a first capacitor CQ, and a second capacitor CQB. According to an example embodiment, the stage ST may further include a bridge voltage transistor Tbv.

The first transistor T1 may be connected between the second power input terminal 126 and the control node CN, and may include a gate electrode connected to the first input terminal 121. The first transistor T1 may be turned on when the start signal VST supplied through the first input signal line IPL1 connected to the first input terminal 121 has a gate-on level, for example, a low level, to electrically connect the fourth power line PL4 connected to the second power input terminal 126 and the control node CN. When the first transistor T1 is turned on, the fourth power voltage VGL supplied through the second power input terminal 126 may be supplied to the control node CN. Although it is described that the gate-on level of the first transistor T1 is a low level, embodiments are not limited thereto. As an example, the gate-on level of the first transistor T1 may be a high level or a low level, depending on the type (e.g., n-type or p-type) of the first transistor T1. The same applies to the remaining transistors of the stage ST included in the gate driver 120.

The second transistor T2 may be connected between the first power input terminal 125 and the control node CN, and may include a gate electrode connected to the second input terminal 122. The second transistor T2 may be turned on when the reset signal QRST supplied through the second input signal line IPL2 connected to the second input terminal 122 has a gate-on level, for example, a low level, to electrically connect the first power line PL1 connected to the first power input terminal 125 and the control node CN. When the second transistor T2 is turned on, the first power voltage VDD supplied through the first power input terminal 125 may be supplied to the control node CN.

The third transistor T3 may be connected between the first power input terminal 125 and the control node CN, and may include a gate electrode connected to the second node QB (or QB node). The third transistor T3 may be turned on or off according to a voltage of the second node QB. For example, the third transistor T3 is turned on when the voltage of the second node QB has a gate-on level, for example, a low level, to electrically connect the first power line PL1 connected to the first power input terminal 125 and the control node CN. When the third transistor T3 is turned on, the first power voltage VDD supplied through the first power input terminal 125 may be supplied to the control node CN.

The fourth transistor T4 may be connected between the second power input terminal 126 and the second node QB, and may include a gate electrode connected to the third input terminal 123. The fourth transistor T4 may be turned on when the first clock signal CLK1 supplied through the first clock line CL1 connected to the third input terminal 123 has a gate-on level, for example, a low level, to electrically connect the fourth power line PL4 connected to the second power input terminal 126 and the second node QB. When the fourth transistor T4 is turned on, the fourth power voltage VGL supplied through the second power input terminal 126 may be supplied to the second node QB.

The fifth transistor T5 may be connected between the first power input terminal 125 and the second node QB, and may include a gate electrode connected to the first input terminal 121. The fifth transistor T5 may be turned on when the start signal VST supplied through the first input signal line IPL1 connected to the first input terminal 121 has a gate-on level, for example, a low level, to electrically connect the first power line PL1 connected to the first power input terminal 125 and the second node QB. When the fifth transistor T5 is turned on, the first power voltage VDD supplied through the first power input terminal 125 may be supplied to the second node QB.

The sixth transistor T6 may be connected between the first power input terminal 125 and the second node QB, and may include a gate electrode connected to the control node CN. The sixth transistor T6 may be turned on or off according to the voltage of the control node CN. The sixth transistor T6 is turned on when the voltage of the control node CN has a gate-on level, e.g., a low level, to electrically connect the first power line PL1 connected to the first power input terminal 125 and the second node QB. When the sixth transistor T6 is turned on, the first power voltage VDD supplied through the first power input terminal 125 may be supplied to the second node QB.

The seventh transistor T7 may be connected between the fourth input terminal 124 and the output terminal 127, and may include a gate electrode connected to the first node Q (or the Q node). For example, a gate electrode of the seventh transistor T7 connected to the first node Q may be connected to the control node CN via the bridge voltage transistor Tbv. The seventh transistor T7 may be turned on or off by the voltage of the first node Q.

Here, the bridge voltage transistor Tbv may be connected between the control node CN and the first node Q, and may include a gate electrode connected to the second power input terminal 126. Since the gate electrode of the bridge voltage transistor Tbv is connected to the second power input terminal 126 connected to the fourth power line PL4 to which the voltage of the fourth power voltage VGL having a gate-on level, for example, a low level is supplied, the bridge voltage transistor Tbv may always maintain a turn-on state. Accordingly, the voltage of the control node CN and the voltage of the first node Q may have substantially the same value. Accordingly, the seventh transistor T7 may be turned on or off according to the voltage of the control node CN. As an example, the bridge voltage transistor Tbv may be omitted depending on the design.

For example, the seventh transistor T7 may be turned on when the voltage of the first node Q or the voltage of the control node CN has a gate-on level, for example, a low level, to electrically connect the fourth input terminal 124 and the output terminal 127. Accordingly, the second clock signal CLK2 provided through the second clock line CL2 connected to the fourth input terminal 124 may be output as the gate signal GATE to the output terminal 127 in the section in which the seventh transistor T7 is turned on.

The eighth transistor T8 may be connected between the first power input terminal 125 and the output terminal 127, and may include a gate electrode connected to the second node QB. The eighth transistor T8 may be turned on or off by the voltage of the second node QB.

For example, the eighth transistor T8 may be turned on when the voltage of the second node QB has a gate-on level, for example, a low level, to electrically connect the first power input terminal 125 and the output terminal 127. Accordingly, in a period in which the eighth transistor T8 is turned on, the gate signal GATE output through the output terminal 127 may have a gate-off level, for example, a high level.

In this way, the seventh transistor T7 may perform a pull-up function, and the eighth transistor T8 may perform a pull-down function.

The first capacitor CQ may be connected between the first node Q and the output terminal 127. For example, the first capacitor CQ may include a first electrode connected to the first node Q and a second electrode connected to the output terminal 127.

The second capacitor CQB may be connected between the second node QB and the first power input terminal 125. For example, the second capacitor CQB may include a first electrode connected to the second node QB and a second electrode connected to the first power input terminal 125. Embodiments are not limited thereto. As an example, the configuration of the stage ST included in the scan driver may be changed in various ways. As an example, at least one or more of the above-mentioned transistors or capacitors may be omitted, or one or more additional transistors or capacitors may be further included.

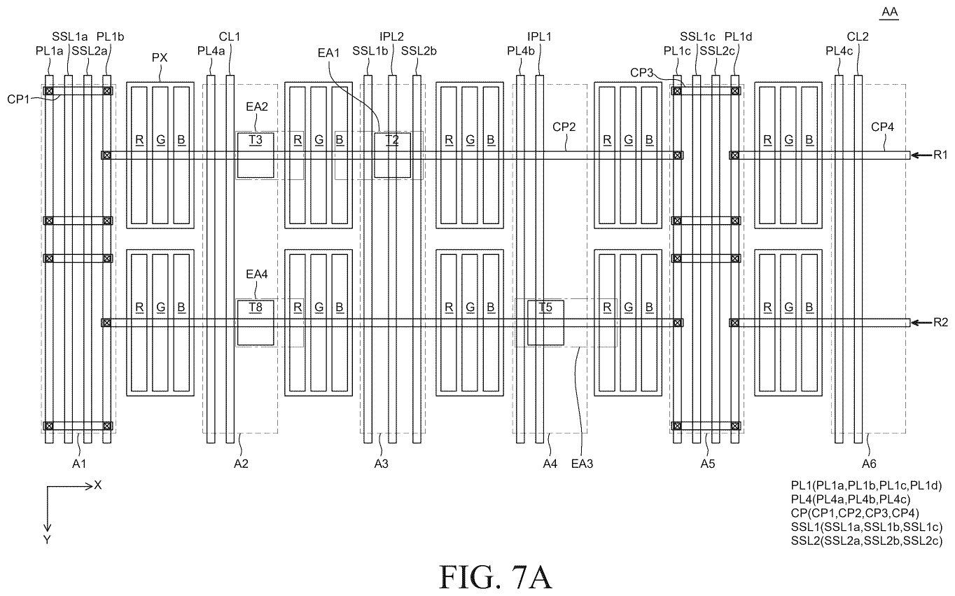

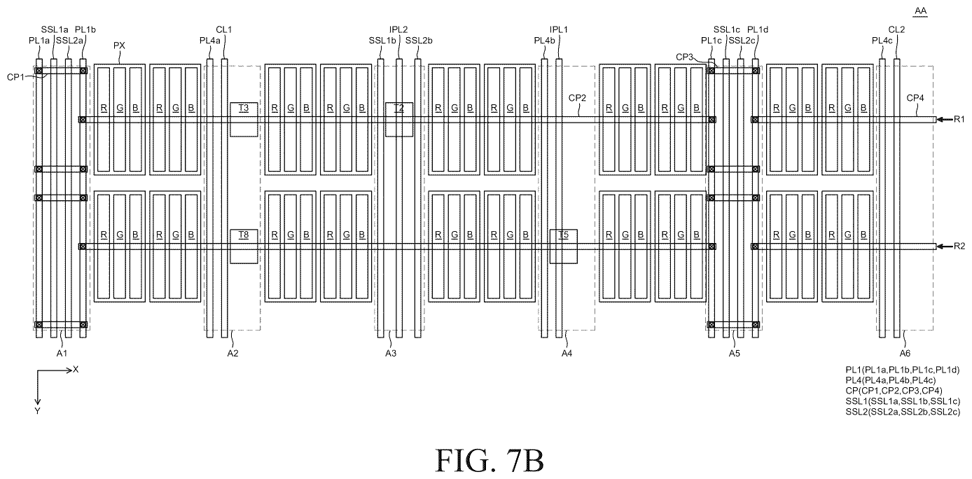

FIG. 7A is a view illustrating an example of a display area of the display device of FIG. 2.

FIG. 7B is a view illustrating another example of the display area of the display device of FIG. 2.

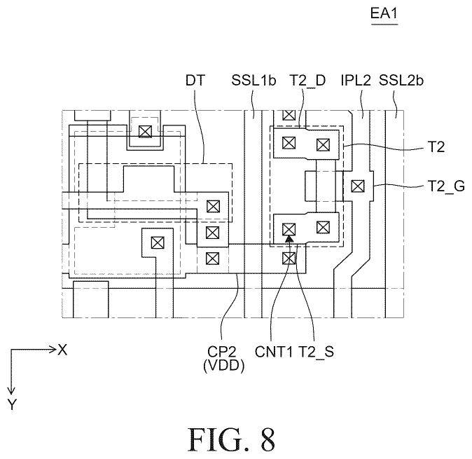

FIG. 8 is an enlarged layout diagram illustrating an example of a part EA1 of FIG. 7A.

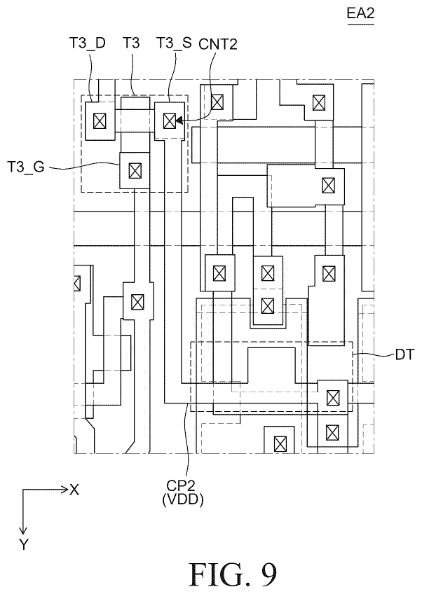

FIG. 9 is an enlarged layout diagram illustrating an example of a part EA2 of FIG. 7A.

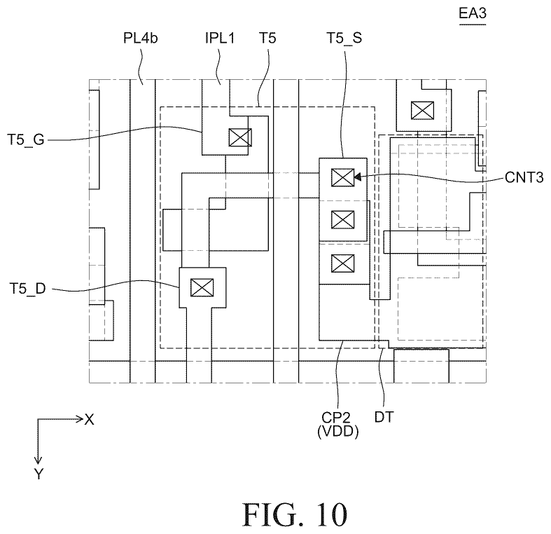

FIG. 10 is an enlarged layout diagram illustrating an example of a part EA3 of FIG. 7A.

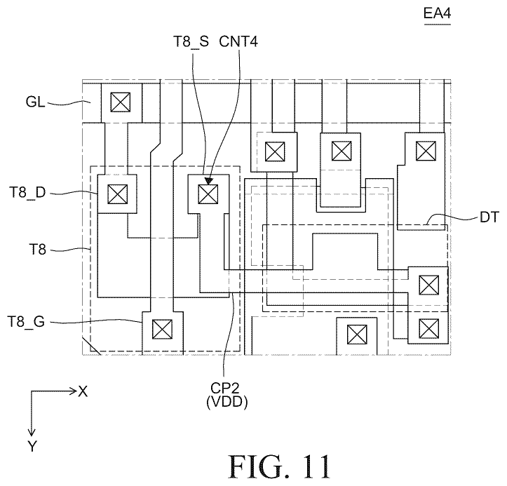

FIG. 11 is an enlarged layout diagram illustrating an example of a part EA4 of FIG. 7A.

As shown in FIGS. 2 and 7A, in an example embodiment, the gate driver 120 may be disposed in the display area AA. For example, the plurality of transistors T1 to T8, the first capacitor CQ, and the second capacitor CQB included in each stage ST included in the gate driver 120 described with reference to FIG. 6 may be disposed and formed between the plurality of pixels PX disposed in the display area AA.

Meanwhile, the display area AA may be divided into a plurality of areas A1 to A6. For example, a plurality of areas A1 to A6 may be sequentially spaced apart from each other along the first direction X. For example, the second area A2 may be disposed at one side along the first direction X of the first area A1, the third area A3 may be disposed at one side along the first direction X of the second area A2, the fourth area A4 may be disposed at one side along the first direction X of the third area A3, the fifth area A5 may be disposed at one side along the first direction X of the fourth area A4, and the sixth area A6 may be disposed at one side along the first direction X of the fifth area A5.

In an example embodiment, at least one pixel PX may be disposed between a plurality of areas A1 to A6 defined in the display area AA. For example, at least one pixel PX may be disposed between the first area A1 and the second area A2, between the second area A2 and the third area A3, between the third area A3 and the fourth area A4, between the fourth area A4 and the fifth area A5, and between the fifth area A5 and the sixth area A6, respectively.

Further, the plurality of pixels PX may be disposed between the plurality of areas A1 to A6 in a first row R1 parallel to the first direction X and a second row R2 adjacent to the first row R1 in the second direction Y and parallel to the first direction X.

Meanwhile, for convenience of description, hereinafter, a horizontal direction on a plane is illustrated as a first direction X, and a vertical direction on a plane is illustrated as a second direction Y. In addition, in the present specification, when the term “overlaps” is used, it means that, unless otherwise defined, the configurations overlap in the thickness direction, for example, in the normal direction of the plane defined according to the first direction X and the second direction Y in the plane.

Each of the plurality of pixels PX may include a plurality of sub pixels R, G, and B emitting light of different colors. For example, each of the plurality of pixels PX may include a first sub-pixel R emitting light of a first color (e.g., red), a second sub-pixel G emitting light of a second color (e.g., green), and a third sub-pixel B emitting light of a third color (e.g., blue). However, the configuration of the sub-pixel is not limited thereto.

According to an example embodiment, the plurality of areas A1 to A6 are areas in which the plurality of pixels PX is not disposed and may be defined as areas that do not overlap the plurality of pixels PX. For example, components (for example, a plurality of transistors T1 to T8 and/or a plurality of capacitors CQ, CQB) included in each stage ST of the gate driver 120 formed in the display area AA in a gate-in-array manner may be disposed on the plurality of areas A1 to A6 of the display area AA together with a plurality of pixels PX and a plurality of wiring lines which transmit signals and voltages for driving various components included in the stage ST.

More specifically, as shown in FIG. 7A, the first power line PL1 configured to provide the first power voltage VDD may be disposed in the first area A1 and the fifth area A5.

For example, the first power line PL1 may include a first sub-power line PL1a and a second sub-power line PL1b disposed in the first area A1, a third sub-power line PL1c and a fourth sub-power line PL1d disposed in the fifth area A5.

In an example embodiment, the first power line PL1 may be disposed in a lattice shape or a mesh shape on the display area AA to be electrically connected to each component of the stage ST of the pixel PX and/or the gate driver 120. To this end, each of the first to fourth sub-power lines PL1a, PL1b, PL1c, and PL1d extends along the second direction Y and may be electrically connected to each other through at least one connection pattern CP extending along the first direction X.

For example, each of the first sub-power line PL1a and the second sub-power line PL1b may be disposed in the first area A1 and electrically connected to at least one first connection pattern CP1 extending along the first direction X through a contact hole. Therefore, the first sub-power line PL1a and the second sub-power line PL1b may be electrically connected to each other through at least one first connection pattern CP1.

Further, each of the second sub-power line PL1b and the third sub-power line PL1c may be electrically connected to at least one second connection pattern CP2 extending along the first direction X and crossing the fifth area A5 from the first area A1 through a contact hole. Therefore, the second sub-power line PL1b and the third sub-power line PL1c may be electrically connected to each other through at least one second connection pattern CP2.

Further, each of the third sub-power line PL1c and the fourth sub-power line PL1d may be disposed in the fifth area A5 and electrically connected to at least one third connection pattern CP3 extending along the first direction X through a contact hole. Therefore, the third sub-power line PL1c and the fourth sub-power line PL1d may be electrically connected to each other through at least one third connection pattern CP3.

Further, the fourth sub-power line PL1d may be electrically connected to the other sub-power line through at least one fourth connection pattern CP4 extending along the first direction X.

In this way, the first power line PL1, which provides the first power voltage VDD, which is a high potential power voltage, is disposed in a lattice shape or a mesh shape on the display area AA to be electrically connected to each component of the stage ST of the pixel PX and/or the gate driver 120. As an example, each stage ST of the gate driver 120 and the pixel PX may share the first power line PL1 configured to provide a high potential voltage, e.g., the first power voltage VDD. As an example, each stage ST of the gate driver 120 and the pixel PX may be commonly connected to the first power line PL1.

In an example embodiment, the first power line PL1 may be formed by being disposed on the same layer as at least one of the bridge electrode BRG, the source electrode SE and the drain electrode DE, and the light shielding layer BM described with reference to FIG. 4 and interconnected with a metal pattern including the same material as at least one of the bridge electrode BRG, the source electrode SE and the drain electrode DE, and the light shielding layer BM described with reference to FIG. 4. Embodiments are not limited thereto. As an example, the first power line PL1 may be separately formed by being disposed on a different layer from the bridge electrode BRG, the source electrode SE and the drain electrode DE, and the light shielding layer BM described with reference to FIG. 4, or interconnected with a pattern including a different material from the bridge electrode BRG, the source electrode SE and the drain electrode DE, and the light shielding layer BM described with reference to FIG. 4, without being limited thereto.

For example, each of the first to fourth sub-power lines PL1a, PL1b, PL1c, and PL1d included in the first power line PL1 and extending in the second direction Y may be disposed on the same layer as the source electrode SE and the drain electrode DE described with reference to FIG. 4 and may include the same material as the source electrode SE and the drain electrode DE described with reference to FIG. 4. However, the present disclosure is not limited thereto, and each of the first to fourth sub-power lines PL1a, PL1b, PL1c, and PL1d may be disposed on the same layer as the bridge electrode BRG described above with reference to FIG. 4 and may include the same material as the bridge electrode BRG.

In addition, each of the first to fourth connection patterns CP1, CP2, CP3, and CP4 included in the first power line PL1 and extending in the first direction X to connect the first to fourth sub-power lines PL1a, PL1b, PL1c, and PL1d to each other may be disposed on the same layer as the light shielding layer BM described with reference to FIG. 4 and may include the same material as the light shielding layer BM described with reference to FIG. 4, without being limited thereto.

Further, as shown in FIG. 7A, the fourth power line PL4 configured to provide the fourth power voltage VGL may be disposed in the second area A2, the fourth area A4, and the sixth area A6.

For example, the fourth power line PL4 may include a fifth sub-power line PL4a disposed in the second area A2 and extending in the second direction Y, a sixth sub-power line PL4b disposed in the fourth area A4 and extending in the second direction Y, and a seventh sub-power line PL4c disposed in the sixth area A6 and extending in the second direction Y.

Meanwhile, although not separately illustrated in FIG. 7A, each of the fifth sub-power line PL4a, the sixth sub-power line PL4b, and the seventh sub-power line PL4c may be electrically connected to each component of the stage ST disposed in the plurality of areas A1 to A6 to provide the fourth power voltage VGL which is a low-potential power voltage.

In an example embodiment, each of the fifth to seventh sub-power lines PL4a, PL4b, and PL4c included in the fourth power line PL4 may be disposed on the same layer as the source electrode SE and the drain electrode DE described above with reference to FIG. 4 and may include the same material as the source electrode SE and the drain electrode DE described above with reference to FIG. 4. However, the present disclosure is not limited thereto, and each of the fifth to seventh sub-power lines PL4a, PL4b, and PL4c may be disposed on the same layer as the bridge electrode BRG described above with reference to FIG. 4 and may include the same material as the bridge electrode BRG described above with reference to FIG. 4, without being limited thereto.

Further, as shown in FIG. 7A, each of the first selection signal line SSL1 configured to provide the first selection signal Ss and the second selection signal line SSL2 configured to provide the second selection signal Ps may be disposed in the first area A1, the third area A3, and the fifth area A5.

For example, the first selection signal line SSL1 may include a first sub-selection signal line SSL1a disposed in the first area A1 and extending along the second direction Y, a second sub-selection signal line SSL1b disposed in the third area A3 and extending along the second direction Y, and a third sub-selection signal line SSL1c disposed in the fifth area A5 and extending along the second direction Y.

Further, the second selection signal line SSL2 may include a fourth sub-selection signal line SSL2a disposed in the first area A1 and extending along the second direction Y, a fifth sub-selection signal line SSL2b disposed in the third area A3 and extending along the second direction Y, and a sixth sub-selection signal line SSL2c disposed in the fifth area A5 and extending along the second direction Y.

In an example embodiment, the first selection signal line SSL1 and the second selection signal line SSL2 disposed in the same area as the first power line PL1 among the plurality of areas A1 to A6 may be disposed between two adjacent first power lines PL1. For example, the first sub-selection signal line SSL1a and the fourth sub-selection signal line SSL2a disposed in the first area A1 may be disposed between the first sub-power line PL1a and the second sub-power line PL1b of the first power line PL1. Similarly, the third sub-selection signal line SSL1c and the sixth sub-selection signal line SSL2c disposed in the fifth area A5 may be disposed between the third sub-power line PL1c and the fourth sub-power line PL1d of the first power line PL1.

Meanwhile, although not separately illustrated in FIG. 7A, each of the first to third sub-selection signal lines SSL1a, SSL1b, and SSL1c may be electrically connected to each of the plurality of pixels PX to provide the first selection signal Ss, and each of the fourth to sixth sub-selection signal lines SSL2a, SSL2b, and SSL2c may be electrically connected to each of the plurality of pixels PX to provide the second selection signal Ps.

In an example embodiment, each of the first to third sub-selection signal lines SSL1a, SSL1b, and SSL1c included in the first selection signal line SSL1 and the fourth to sixth sub-selection signal lines SSL2a, SSL2b, and SSL2c included in the second selection signal line SSL2 may be disposed on the same layer as the source electrode SE and the drain electrode DE described with reference to FIG. 4 and may include the same material as the source electrode SE and the drain electrode DE described with reference to FIG. 4. However, the present disclosure is not limited thereto. Each of the first to third sub-selection signal lines SSL1a, SSL1b, and SSL1c included in the first selection signal line SSL1 and the fourth to sixth sub-selection signal lines SSL2a, SSL2b, and SSL2c included in the second selection signal line SSL2 may be disposed on the same layer as the bridge electrode BRG described above with reference to FIG. 4 and may include the same material as the bridge electrode BRG described above with reference to FIG. 4, without being limited thereto.

Further, as shown in FIG. 7A, the first input signal line IPL1 configured to provide the start signal VST may be disposed in the fourth area A4 so as to extend in the second direction Y, and the second input signal line IPL2 configured to provide the reset signal QRST may be disposed in the third area A3 so as to extend in the second direction Y.

For example, the first input signal line IPL1 may be disposed on one side of the fourth power line PL4, e.g., the sixth sub-power line PL4b disposed in the fourth area A4, along the first direction X. For example, in the fourth area A4, the sixth sub-power line PL4b may be disposed to be adjacent to the third area A3, and the first input signal line IPL1 may be disposed to be adjacent to the fifth area A5.

In an example embodiment, the second input signal line IPL2 may be disposed between the first selection signal line SSL1 and the second selection signal line SSL2 disposed in the third area A3. For example, the second input signal line IPL2 may be disposed between the second sub-selection signal line SSL1b and the fifth sub-selection signal line SSL2b.

Meanwhile, although not separately illustrated in FIG. 7A, each of the first input signal line IPL1 and the second input signal line IPL2 may be electrically connected to each component of the stage ST disposed in the plurality of areas A1 to A6 to provide the start signal VST and the reset signal QRST.

Further, as shown in FIG. 7A, the first clock line CL1 configured to provide the first clock signal CLK1 may be disposed in the second area A2 to extend along the second direction Y, and the second clock line CL2 configured to provide the second clock signal CLK2 may be disposed to extend along the second direction Y in the sixth area A6.

For example, the first clock line CL1 may be disposed on one side of the fourth power line PL4, e.g., the fifth sub-power line PL4a disposed in the second area A2 along the first direction X. For example, in the second area A2, the fifth sub-power line PL4a may be disposed to be adjacent to the first area A1, and the first clock line CL1 may be disposed to be adjacent to the third area A3.

Further, the second clock line CL2 may be disposed at one side of the fourth power line PL4, e.g., the seventh sub-power line PL4c disposed in the sixth area A6, along the first direction X. For example, in the sixth area A6, the seventh sub-power line PL4c may be disposed to be adjacent to the fifth area A5 and the second clock line CL2 may be disposed to be adjacent to an opposite side of the fifth area A5.

Meanwhile, although not separately illustrated in FIG. 7A, each of the first clock line CL1 and the second clock line CL2 may be electrically connected to each component of the stage ST disposed in the plurality of areas A1 to A6 to provide the first clock signal CLK1 and the second clock signal CLK2.

In an example embodiment, at least one of the first input signal line IPL1, the second input signal line IPL2, the first clock line CL1, and the second clock line CL2 may be disposed on the same layer as the source electrode SE and the drain electrode DE described with reference to FIG. 4 and may include the same material as the source electrode SE and the drain electrode DE described with reference to FIG. 4. However, the present disclosure is not limited thereto, and at least one of the first input signal line IPL1, the second input signal line IPL2, the first clock line CL1, and the second clock line CL2 may be disposed on the same layer as the bridge electrode BRG described above with reference to FIG. 4 and may include the same material as the bridge electrode BRG described above with reference to FIG. 4, without being limited thereto.

Meanwhile, in FIG. 7A, only a part of signal lines and/or power lines disposed in the plurality of areas A1 to A6 may be shown. For example, as described above, the fourth power line PL4, the first selection signal line SSL1, the second selection signal line SSL2, the first input signal line IPL1, the second input signal line IPL2, the first clock line CL1 and/or the second clock line CL2 may also be electrically connected to each component of the plurality of pixels PX and/or the stage ST through at least one connection pattern extending along the first direction X substantially the same as or similar to the first power line PL1 to provide various signals, power voltages, and the like. Embodiments are not limited thereto. As an example, at least one of the connection patterns may extend along a direction other than the first direction X, such as the second direction Y or a direction between the first direction X and the second direction Y, without being limited thereto.

In an example embodiment, as illustrated in FIG. 7A, one pixel PX may be disposed between a plurality of areas A1 to A6 based on one pixel row. For example, an interval between a plurality of areas A1 to A6 in which various signal lines and power lines are disposed may correspond to a width of one pixel PX along the first direction X.

However, the example embodiment of the present disclosure is not limited thereto. For example, as shown in FIG. 7B, two pixels PX may be disposed between the plurality of areas A1 to A6 based on one pixel row. For example, the interval between the plurality of areas A1 to A6 may have a width corresponding to twice the width of one pixel PX along the first direction X. Embodiments are not limited thereto. As an example, three or more pixels PX may be disposed between the plurality of areas A1 to A6 based on one pixel row. As an example, the number of pixels PX disposed between adjacent areas among the plurality of areas A1 to A6 may be constant or variable, without being limited thereto.

That is, as illustrated in FIG. 7A, one pixel PX is disposed between the plurality of areas A1 to A6 based on one pixel row with respect to the scan driver of the gate driver 120, such that an interval between a plurality of areas A1 to A6 in which power lines and various signal lines constituting the scan driver are disposed may correspond to a width of one pixel PX according to the first direction X. In addition, as illustrated in FIG. 7B, two pixels PX are disposed between the plurality of areas A1 to A6 with respect to the emission driver of the gate driver 120, based on one pixel row, such that an interval between a plurality of areas A1 to A6 in which power lines and various signal lines constituting the emission driver are disposed may correspond to twice the width of one pixel PX according to the first direction X.

As shown in FIG. 7A, in an example embodiment, each stage ST of the gate driver 120 may be disposed in the display area AA. For example, a plurality of transistors T1 to T8 and a plurality of capacitors CQ and CQB included in each stage ST of the gate driver 120 may be disposed in a plurality of areas A1 to A6 in which various signal lines and power lines are disposed. For example, the plurality of transistors T1 to T8 and the plurality of capacitors CQ and CQB included in each stage ST of the gate driver 120 may be disposed not to overlap the plurality of pixels PX on the display area AA, or may be disposed to partially overlap the plurality of pixels PX on the display area AA.

Meanwhile, for convenience of description, FIGS. 7A and 7B illustrate a second transistor T2, a third transistor T3, a fifth transistor T5, and an eighth transistor T8 which are transistors connected to the first power line PL1, a power line shared with the pixel PX, among a plurality of transistors T1 to T8 included in each stage ST of the gate driver 120. Further, FIGS. 8 to 11 illustrate an enlarged layout diagram of areas in which the second transistor T2, the third transistor T3, the fifth transistor T5, and the eighth transistor T8 illustrated in FIG. 6 are disposed.

First, to describe the arrangement and connection relationship of the second transistor T2, as shown in FIGS. 7A and 8 together, the second transistor T2 may be disposed in the third area A3. For example, the second transistor T2 may be disposed on the third area A3 at a position corresponding to the first row R1.

For example, the second transistor T2 includes a gate electrode T2_G, a source electrode T2_S, and a drain electrode T2_D and may be disposed between the second sub-selection signal line SSL1b and the second input signal line IPL2. Further, as illustrated in FIG. 8, the gate electrode T2_G of the second transistor T2 extends along the first direction X and is electrically connected to the second input signal line IPL2 through at least one contact hole to receive the reset signal QRST from the second input signal line IP2.

In an example embodiment, the source electrode T2_S (or the drain electrode T2_D) of the second transistor T2 may be electrically connected to the first power line PL1 which transmits the first power voltage VDD through the connection pattern CP. For example, the source electrode T2_S (or the drain electrode T2_D) of the second transistor T2 may be connected to the first power line PL1 and electrically connected to the second connection pattern CP2 extending along the first direction X through the first contact hole CNT1. Accordingly, one electrode (e.g., the source electrode T2_S or the drain electrode T2_D) of the second transistor T2 may be electrically connected to the first power line PL1 to receive the first power voltage VDD, which is a high potential power voltage.

Meanwhile, as illustrated in FIG. 8, the driving transistor DT included in the third sub pixel B of the pixel PX may be disposed on one side of the third area A3 along a direction opposite to the first direction X. The driving transistor DT may also be connected to the second connection pattern CP2 to receive the first power voltage VDD from the first power line PL1.

Next, as shown in FIGS. 7A and 9 together to describe the arrangement and connection relationship of the third transistor T3, the third transistor T3 may be disposed in the second area A2. For example, the third transistor T3 may be disposed on the second area A2 at a position corresponding to the first row R1.

For example, the third transistor T3 includes a gate electrode T3_G, a source electrode T3_S, and a drain electrode T3_D and may be disposed at one side of the first clock line CL1 along the first direction X. For example, the third transistor T3 may be disposed between the first clock line CL1, and the pixel PX disposed between the third area A3 and the second area A2.

In an example embodiment, as illustrated in FIG. 9, the source electrode T3_S (or the drain electrode T3_D) of the third transistor T3 may be electrically connected to the first power line PL1 which transmits the first power voltage VDD through the connection pattern CP. For example, at least a part of the source electrode T3_S (or the drain electrode T3_D) of the third transistor T3 may extend in the second direction Y and may be electrically connected to the second connection pattern CP2 extending along the first direction X through the second contact hole CNT2. Accordingly, one electrode (e.g., the source electrode T3_S or the drain electrode T3_D) of the third transistor T3 may be electrically connected to the first power line PL1 to receive the first power voltage VDD, which is a high potential power voltage.

Meanwhile, as illustrated in FIG. 9, the driving transistor DT included in the first sub pixel R of the pixel PX may be disposed at one side of the second area A2 along the first direction X. The driving transistor DT may also be connected to the second connection pattern CP2 to receive the first power voltage VDD from the first power line PL1.

Next, to describe the arrangement and connection relationship of the fifth transistor T5 as shown in FIGS. 7A and 10 together, the fifth transistor T5 may be disposed in the fourth area A4. For example, the fifth transistor T5 may be disposed on the fourth area A4 at a position corresponding to the second row R2.

For example, the fifth transistor T5 includes a gate electrode T5_G, a source electrode T5_S, and a drain electrode T5_D and may be disposed on one side of the sixth sub-power line PL4b in the first direction X. For example, the fifth transistor T5 may be disposed to overlap a position where the first input signal line IPL1 is disposed.

Further, as illustrated in FIG. 10, the gate electrode T5_G of the fifth transistor T5 is electrically connected to the first input signal line IPL1 through at least one contact hole to receive the start signal VST from the first input signal line IPL1.

In an example embodiment, as illustrated in FIG. 10, the source electrode T5_S (or the drain electrode T5_D) of the fifth transistor T5 may be electrically connected to the first power line PL1 which transmits the first power voltage VDD through the connection pattern CP. For example, the second connection pattern CP2 extending in the first direction X includes a protrusion protruding in the second direction Y, and at least a part of the protrusion of the second connection pattern CP2 and the source electrode T5_S (or the drain electrode T5_D) of the fifth transistor T5 may be electrically connected through the third contact hole CNT3. Accordingly, one electrode (e.g., the source electrode T5_S or the drain electrode T5_D) of the fifth transistor T5 is electrically connected to the first power line PL1 to receive the first power voltage VDD, which is a high potential power voltage.

Meanwhile, as illustrated in FIG. 10, the driving transistor DT included in the first sub pixel R of the pixel PX may be disposed at one side of the fourth area A4 along the first direction X. The driving transistor DT may also be connected to the second connection pattern CP2 to receive the first power voltage VDD from the first power line PL1.

Next, to describe the arrangement and connection relationship of the eighth transistor T8, as shown in FIGS. 7A and 11 together, the eighth transistor T8 may be disposed in the second area A2. For example, the eighth transistor T8 may be disposed on the second area A2 at a position corresponding to the second row R2.

For example, the eighth transistor T8 includes a gate electrode T8_G, a source electrode T8_S, and a drain electrode T8_D and may be disposed at one side of the first clock line CL1 along the first direction X. For example, the eighth transistor T8 may be disposed between the first clock line CL1, and the pixel PX disposed between the third area A3 and the second area A2.

In an example embodiment, the source electrode T8_S (or the drain electrode T8_D) of the eighth transistor T8 may be electrically connected to the first power line PL1 which transmits the first power voltage VDD through the connection pattern CP. For example, at least a part of the source electrode T8_S (or the drain electrode T8_D) of the eighth transistor T8 extends in the second direction Y and may be electrically connected to the second connection pattern CP2 extending along the first direction X through the fourth contact hole CNT4. Accordingly, one electrode (e.g., the source electrode T8_S or the drain electrode T8_D) of the eighth transistor T8 is electrically connected to the first power line PL1 to receive the first power voltage VDD, which is a high potential power voltage.

Further, as illustrated in FIG. 11, the drain electrode T8_D (or the source electrode T8_S) of the eighth transistor T8 may be connected to the gate line GL through at least one contact hole. Accordingly, when the eighth transistor T8 is turned on, a voltage output from the eighth transistor T8, for example, a high level of first power voltage VDD supplied from the first power line PL1 through the second connection pattern CP2 may be output through the gate line GL.

Meanwhile, as illustrated in FIG. 11, the driving transistor DT included in the first sub pixel R of the pixel PX may be disposed at one side of the second area A2 along the first direction X. The driving transistor DT may also be connected to the second connection pattern CP2 to receive the first power voltage VDD from the first power line PL1.

In an example embodiment, transistors (e.g., the second transistor T2, the third transistor T3, the fifth transistor T5, and/or the eighth transistor T8) included in each stage ST of the gate driver 120 described with reference to FIGS. 7A to 11 may be electrically connected to the connection pattern CP connected to the first power line PL1 through a metal pattern. For example, the metal pattern may be disposed on the same layer as at least one of various metal layers constituting the transistor of the pixel PX and include the same metal material as at least one of various metal layers constituting the transistor of the pixel PX, but is not limited thereto.

As described above, in the display device 100 according to example embodiments of the present disclosure, various components (e.g., a plurality of transistors T1 to T8, a plurality of capacitors CQ, CQB, etc.) included in each stage ST of the gate driver 120, and wiring lines connected thereto, which provide various signals and voltages, are disposed in the display area AA (e.g., a gate-in-array structure). Therefore, a bezel area of the display device 100 may be minimized or reduced.

Further, unlike a conventional display device in which a high potential power voltage is provided to each stage ST of the gate driver 120 through a separate power line separately from a power line (for example, a first power line PL1) for providing a high potential power voltage to the pixel PX, the display device 100 according to example embodiments of the present disclosure may provide a high potential power voltage (for example, a first power voltage VDD) to each stage ST of the gate driver 120 by using a power line (for example, a first power line PL1) for providing a high potential power voltage (for example, a first power voltage VDD) to the pixel PX. That is, in the display device 100 according to example embodiments of the present disclosure, each stage ST of the pixel PX and the gate driver 120 may share the first power line PL1 that provides the first power voltage VDD. Accordingly, since the number of power lines decreases in the display area AA, pattern density may be improved, and parasitic capacitance between lines may be minimized or reduced.

Meanwhile, FIGS. 7A to 11 may show only some of the configurations of each stage ST disposed in a plurality of areas A1 to A6. For example, in the plurality of areas A1 to A6, transistors (e.g., the first transistor T1, the fourth transistor T4, the sixth transistor T6, the seventh transistor T7, etc.) and capacitors (e.g., the first capacitor CQ, the second capacitor CQB, etc.) of each stage ST described with reference to FIG. 6 may be disposed, in addition to the second transistor T2, the third transistor T3, the fifth transistor T5, and the eighth transistor T8 illustrated in FIGS. 7A to 11.

Various example embodiments of the present disclosure can also be described as follows:

To achieve the objects as described above and in accordance with an aspect of the present disclosure, a display device includes: at least one pixel disposed on a display area and including at least one light emitting element, the at least one light emitting element emitting light based on a first power voltage, a second power voltage, a third power voltage, a gate signal, and a data signal; and a gate driver disposed on the display area and including at least one stage, the at least one stage generating the gate signal based on the first power voltage, a fourth power voltage, a start signal, a reset signal, a first clock signal, and a second clock signal. The display area includes a plurality of areas that do not overlap the at least one pixel, the at least one stage is disposed in the plurality of areas. The at least one pixel and the at least one stage share at least one power line.

In an example embodiment, the at least one pixel and the at least one stage may be commonly connected to a first power line configured to provide the first power voltage and disposed in the plurality of areas.

In an example embodiment, the plurality of areas may include first to sixth areas sequentially spaced apart along a first direction, and the at least one pixel may be disposed between the first to sixth areas.

In an example embodiment, a first power line configured to provide the first power voltage may include: a first sub-power line disposed in the first area and extending in a second direction different from the first direction; a second sub-power line disposed in the first area and extending in the second direction; a third sub-power line disposed in the fifth area and extending in the second direction; and a fourth sub-power line disposed in the fifth area and extending in the second direction.

In an example embodiment, the first sub-power line, the second sub-power line, the third sub-power line, and the fourth sub-power line may be electrically connected to each other by at least one connection pattern extending in the first direction.

In an example embodiment, at least one transistor included in the at least one stage may be disposed in any one of the first to sixth areas, and the at least one transistor may be connected to the at least one connection pattern.

In an example embodiment, at least one transistor included in the at least one pixel may be connected to the at least one connection pattern.

In an example embodiment, a fourth power line configured to provide the fourth power voltage may include: a fifth sub-power line disposed in the second area and extending in the second direction; a sixth sub-power line disposed in the fourth area and extending in the second direction; and a seventh sub-power line disposed in the sixth area and extending in the second direction.

In an example embodiment, the at least one pixel may include: a first light emitting element; a second light emitting element; a driving transistor connected between the first power line and a second power line configured to provide the second power voltage, the driving transistor being configured to control a first driving current and second driving current, the first driving current flowing from the first power line to the second power line via the first light emitting element, and the second driving current flowing from the first power line to the second power line via the second light emitting element; a first selection transistor controlling a current path of the first driving current in response to a first selection signal; and a second selection transistor controlling a current path of the second driving current in response to a second selection signal.

In an example embodiment, the display device may further include a first selection signal line providing the first selection signal. The first selection signal line may include a first sub-selection signal line extending in the second direction on the first area and disposed between the first sub-power line and the second sub-power line; a second sub-selection signal line disposed in the third area and extending in the second direction; and a third sub-selection signal line extending in the second direction on the fifth area and disposed between the third sub-power line and the fourth sub-power line.

In an example embodiment, the display device may further include a second selection signal line configured to provide the second selection signal. The second selection signal line may include: a fourth sub-selection signal line extending in the second direction on the first area and disposed between the first sub-power line and the second sub-power line; a fifth sub-selection signal line disposed in the third area and extending in the second direction; and a sixth sub-selection signal line extending in the second direction on the fifth area and disposed between the third sub-power line and the fourth sub-power line.

In an example embodiment, the display device may further include a first input signal line configured to provide the start signal and a second input signal line configured to provide the reset signal. The first input signal line may be disposed at one side along the first direction of the sixth sub-power line in the fourth area, and the second input signal line may be disposed between the second sub-selection signal line and the fifth sub-selection signal line in the third area.

In an example embodiment, the display device may further include a first clock line configured to provide the first clock signal and a second clock line configured to provide the second clock signal. The first clock line may be disposed at one side along the first direction of the fifth sub-power line in the second area, and the second clock line may be disposed at one side along the first direction of the seventh sub-power line in the sixth area.

In an example embodiment, one pixel may be disposed between each of the first to sixth areas based on one pixel row.

In an example embodiment, two pixels may be disposed between each of the first to sixth areas based on one pixel row.

In another aspect of the present disclosure, a display device includes at least one pixel disposed in a display area including a plurality of areas that are sequentially spaced apart along a first direction, the at least one pixel being disposed so as not to overlap the plurality of areas; a gate driver including at least one stage disposed in the plurality of areas on the display area; at least one power line disposed in the plurality of areas and extending in a second direction different from the first direction; and at least one connection pattern extending in the first direction and connected to the at least one power line. At least one transistor included in the at least one stage is connected to the at least one connection pattern, and at least one transistor included in the at least one pixel is connected to the at least one connection pattern.

Although various example embodiments of the present disclosure have been described in detail with reference to the accompanying drawings, the present disclosure is not limited thereto and may be embodied in various forms without departing from the technical concept of the present disclosure. Therefore, these example embodiments of the present disclosure are provided for illustrative purposes only and are not intended to limit the technical concept of the present disclosure. The scope of the technical concept of the present disclosure is not limited thereto. Therefore, it should be understood that the above-described embodiments are examples in all aspects and are not limiting. The protective scope of the present disclosure may be construed based on the following claims and their equivalents, and all the technical concepts in the equivalent scope thereof should be construed as falling within the scope of the present disclosure.

What is claimed is:

1. A display device, comprising:
at least one pixel disposed on a display area and each including at least one light emitting element, the at least one light emitting element emitting light based on a first power voltage, a second power voltage, a gate signal, and a data signal; and
a gate driver disposed on the display area and including at least one stage, the at least one stage each configured to generate the gate signal based on the first power voltage, and
wherein the at least one pixel and the at least one stage share at least one power line.

2. The display device according to claim 1, wherein the display area includes a plurality of areas that do not overlap the at least one pixel, each of the at least one stage disposed in the plurality of areas.

3. The display device according to claim 2, wherein the at least one light emitting element emits light further based on a third power voltage, and
each of the at least one stage is configured to generate the gate signal based on the first power voltage, a fourth power voltage, a start signal, a reset signal, a first clock signal, and a second clock signal.

4. The display device according to claim 2, wherein the at least one pixel and the at least one stage are commonly connected to a first power line configured to provide the first power voltage and disposed in the plurality of areas.

5. The display device according to claim 3, wherein:
the plurality of areas includes first to sixth areas sequentially spaced apart along a first direction in which a gate line for outputting the gate signal extends; and
the at least one pixel is disposed between the first to sixth areas.

6. The display device according to claim 5, wherein a first power line configured to provide the first power voltage includes:
a first sub-power line disposed in the first area and extending in a second direction different from the first direction;
a second sub-power line disposed in the first area and extending in the second direction;
a third sub-power line disposed in the fifth area and extending in the second direction; and
a fourth sub-power line disposed in the fifth area and extending in the second direction.

7. The display device according to claim 6, wherein the first sub-power line, the second sub-power line, the third sub-power line, and the fourth sub-power line are electrically connected to each other by at least one connection pattern extending in the first direction.

8. The display device according to claim 7, wherein:
at least one transistor included in the at least one stage is disposed in any one of the first to sixth areas; and
the at least one transistor is connected to the at least one connection pattern.

9. The display device according to claim 7, wherein at least one transistor included in the at least one pixel is connected to the at least one connection pattern.

10. The display device according to claim 6, further comprising a fourth power line,
wherein the fourth power line configured to provide the fourth power voltage includes:
a fifth sub-power line disposed in the second area and extending in the second direction;
a sixth sub-power line disposed in the fourth area and extending in the second direction; and
a seventh sub-power line disposed in the sixth area and extending in the second direction.

11. The display device according to claim 10, wherein each of the at least one pixel includes:
a first light emitting element;
a second light emitting element;
a driving transistor connected between the first power line and a second power line configured to provide the second power voltage, the driving transistor being configured to control a first driving current and second driving current, the first driving current flowing from the first power line to the second power line via the first light emitting element, and the second driving current flowing from the first power line to the second power line via the second light emitting element;
a first selection transistor configured to control a current path of the first driving current in response to a first selection signal; and
a second selection transistor configured to control a current path of the second driving current in response to a second selection signal.

12. The display device according to claim 11, further comprising a first selection signal line providing the first selection signal,
wherein the first selection signal line includes:
a first sub-selection signal line extending in the second direction on the first area and disposed between the first sub-power line and the second sub-power line;
a second sub-selection signal line disposed in the third area and extending in the second direction; and
a third sub-selection signal line extending in the second direction on the fifth area and disposed between the third sub-power line and the fourth sub-power line.

13. The display device according to claim 12, further comprising a second selection signal line configured to provide the second selection signal,
wherein the second selection signal line includes:
a fourth sub-selection signal line extending in the second direction on the first area and disposed between the first sub-power line and the second sub-power line;
a fifth sub-selection signal line disposed in the third area and extending in the second direction; and
a sixth sub-selection signal line extending in the second direction on the fifth area and disposed between the third sub-power line and the fourth sub-power line.

14. The display device according to claim 13, further comprising:
a first input signal line configured to provide the start signal; and
a second input signal line configured to provide the reset signal,
wherein the first input signal line is disposed at one side along the first direction of the sixth sub-power line in the fourth area, and
wherein the second input signal line is disposed between the second sub-selection signal line and the fifth sub-selection signal line in the third area.

15. The display device according to claim 11, wherein each of the at least one pixel further includes:
a first optical member that refracts light from the first light emitting element to provide light in a first range; and
a second optical member that refracts light from the second light emitting element to provide light in a second range narrower than the first range.

16. The display device according to claim 10, further comprising:
a first clock line configured to provide the first clock signal; and
a second clock line configured to provide the second clock signal,
wherein the first clock line is disposed at one side along the first direction of the fifth sub-power line in the second area, and
wherein the second clock line is disposed at one side along the first direction of the seventh sub-power line in the sixth area.

17. The display device according to claim 5, wherein one pixel or two pixels are disposed between every two adjacent areas of the first to sixth areas based on one pixel row.

18. The display device according to claim 2, wherein the plurality of areas are sequentially spaced apart along a first direction in which a gate line for outputting the gate signal extends, and
two rows of pixels adjacent to each other in a second direction different from the first direction are disposed between the plurality of areas.

19. The display device according to claim 2, wherein the plurality of areas are sequentially spaced apart along a first direction in which a gate line for outputting the gate signal extends, and
an interval between the plurality of areas correspond to a width of one pixel along the first direction, or twice the width.

20. A display device, comprising:
at least one pixel disposed in a display area including a plurality of areas that are sequentially spaced apart along a first direction, the at least one pixel being disposed so as not to overlap the plurality of areas;
a gate driver including at least one stage disposed in the plurality of areas on the display area;
at least one power line disposed in the plurality of areas and extending in a second direction different from the first direction; and
at least one connection pattern extending in the first direction and connected to the at least one power line,
wherein at least one transistor included in the at least one stage is connected to the at least one connection pattern, and
wherein at least one transistor included in the at least one pixel is connected to the at least one connection pattern.
